(19) United States
(12) Patent Application Publication
(10) Pub. No.: US 2012/0279438 A1
(43) Pub. Date: Nov. 8, 2012

(54) METHODS FOR PRODUCING SINGLE CRYSTAL SILICON INGOTS WITH REDUCED INCIDENCE OF DISLOCATIONS

(75) Inventors: Jae Woo Ryu, Ballwin, MO (US); Young Gil Jeong, St. Peters, MO (US)

(73) Assignee: MEMC ELECTRONIC MATERIALS, INC., St. Peters, MO (US)

(21) Appl. No.: 13/454,676

(22) Filed: Apr. 24, 2012

Related U.S. Application Data
(60) Provisional application No. 61/481,911, filed on May 3, 2011.

(51) Int. Cl. C30B 15/22

(52) U.S. Cl. 117/35

(57) ABSTRACT

Methods for reducing or even eliminating dislocations in Czochralski-grown silicon ingots are disclosed. Generally, the methods involve controlling the growth conditions of the neck prior to formation of the ingot body.

### CROSS-REFERENCE TO RELATED APPLICATION

This application claims the benefit of U.S. Provisional Patent Application No. 61/481,911, filed May 3, 2011, which is incorporated herein by reference.

### BACKGROUND

The field of this disclosure relates to production of single crystal silicon ingots by the Czochralski method and, in particular, relates to methods for reducing or even eliminating dislocations in the silicon ingot by controlling the growth conditions of the neck prior to formation of the ingot body.

Single crystal silicon, which is the starting material for most processes for the fabrication of semiconductor electronic components, is commonly prepared by the Czochralski (“Cz”) method. In this method, polycrystalline silicon (“polysilicon”) is charged to a crucible and melted, a seed crystal is brought into contact with the molten silicon and a single crystal is grown by slow extraction. As crystal growth is initiated, dislocations are generated in the crystal from the thermal shock of contacting the seed crystal with the melt. These dislocations are propagated throughout the growing crystal and multiplied unless they are eliminated in a neck region between the seed crystal and the main body of the crystal.

Conventional methods for eliminating dislocations within a silicon single crystal include the so-called “dash neck method” which involves growing a neck having a small diameter (e.g., 2 to 4 mm) at a high crystal pull rate (e.g., as high as 6 mm/min) to completely eliminate dislocations before initiating growth of the main body of crystal. Generally, dislocations can be eliminated in these small diameter necks after approximately 100 to about 125 mm of the neck has been grown. Once the dislocations have been eliminated, the diameter of the crystal is enlarged to form a “cone” or “taper” portion. When the desired diameter of the crystal is reached, the cylindrical main body is then grown to have an approximately constant diameter.

In some instances the neck, which is the weakest part of the silicon single crystal, can fracture during crystal growth, causing the body of the crystal to drop into the crucible. Conventional crystals having a Dash neck are typically grown to a weight of 100 kg or less to minimize stress on the neck. However, in recent years, progress in the semiconductor industry has created an ever-increasing demand for larger silicon wafers of a high quality. Particularly, more highly integrated semiconductor devices have resulted in increased chip areas and a demand for the production of silicon wafers having a diameter of 200 mm, 300 mm or more or even 450 mm or more.

Thus, a continuing need exists for more effective neck growth processes which allow large diameter ingots of substantial weight to be grown and which decrease the likelihood that dislocations form in the ingot and that prevent the neck from fracturing in such ingots.

### SUMMARY

One aspect of the present disclosure is directed to a method for producing a single crystal silicon ingot. The ingot has a neck, an outwardly flaring cone adjacent the neck and a main body with a constant diameter portion adjacent the cone. The constant diameter portion has a circumferential edge, a central axis that is parallel to the circumferential edge and a radius that extends from the central axis to the circumferential edge. The central axis passes through the cone and neck. A seed crystal is brought into contact with a silicon melt. The seed crystal is withdrawn from the silicon melt to form a neck adjacent the seed crystal. An outwardly flaring cone adjacent the neck is grown. A growth velocity V and/or a temperature gradient G_{Hr} are controlled during formation of a terminal portion of the neck, such that the ratio V/G_{Hr} is controlled to be from about 0.80 to about 0.96 mm²/min*K. The terminal portion of the neck extends axially from the outwardly flaring cone portion to a distance of at least about 4 inches (about 10.16 cm) from the outwardly flaring cone portion. A main ingot body having a constant diameter adjacent the cone is grown.

Another aspect of the present disclosure is directed to a method for producing a single crystal silicon ingot. The ingot has a neck, an outwardly flaring cone adjacent the neck and a main body with a constant diameter portion adjacent the cone. The constant diameter portion has a circumferential edge, a central axis that is parallel to the circumferential edge and a radius that extends from the central axis to the circumferential edge. The central axis passes through the cone and neck. A seed crystal is brought into contact with a silicon melt. The seed crystal is withdrawn from the silicon melt to form a neck adjacent the seed crystal. An outwardly flaring cone adjacent the neck is grown. A growth velocity V is controlled according to equation (1) during formation of a terminal portion of the neck:

V=−2.826 In (Hᵣ)+14.76 (1).

Hᵣ is the distance between the melt-solid interface and a device positioned above the melt-solid interface selected from the group consisting of a reflector, a radiation shield, a heat shield, an insulating ring and a purge tube. The terminal portion of the neck extends axially from the outwardly flaring cone portion to a distance of at least about 4 inches (about 10.16 cm) from the outwardly flaring cone portion. A main ingot body is grown having a constant diameter adjacent the cone.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a partial front view of a single crystal silicon ingot grown by the Czochralski method;

FIG. 2 is a cross-section of a crystal puller apparatus used to pull a single crystal silicon ingot from a silicon melt;

FIG. 3 is a scatter-plot showing the relationship between the ratio V/G_{Hr} and dislocation formation;

FIG. 4 is a contour plot showing the relationship between the ratio V/G_{Hr} and Hᵣ and dislocation formation;

FIG. 5 is a scatter-plot showing etch pit density along the length of several ingot necks formed with different axial temperature gradients G_{Hr}; and

FIG. 6 is a box-plot showing V/G_{Hr} for zero-dislocation ingots for a variety of reflector heights Hᵣ.

Corresponding reference characters indicate corresponding parts throughout the drawings.

### DETAILED DESCRIPTION

In accordance with the present disclosure, methods for reducing or even eliminating the number of dislocations that form in the main body portion of a silicon ingot are provided. Generally the methods involve controlling one or more growth parameters during the at least about the last 4 inches (about 10.16 cm) of neck growth.

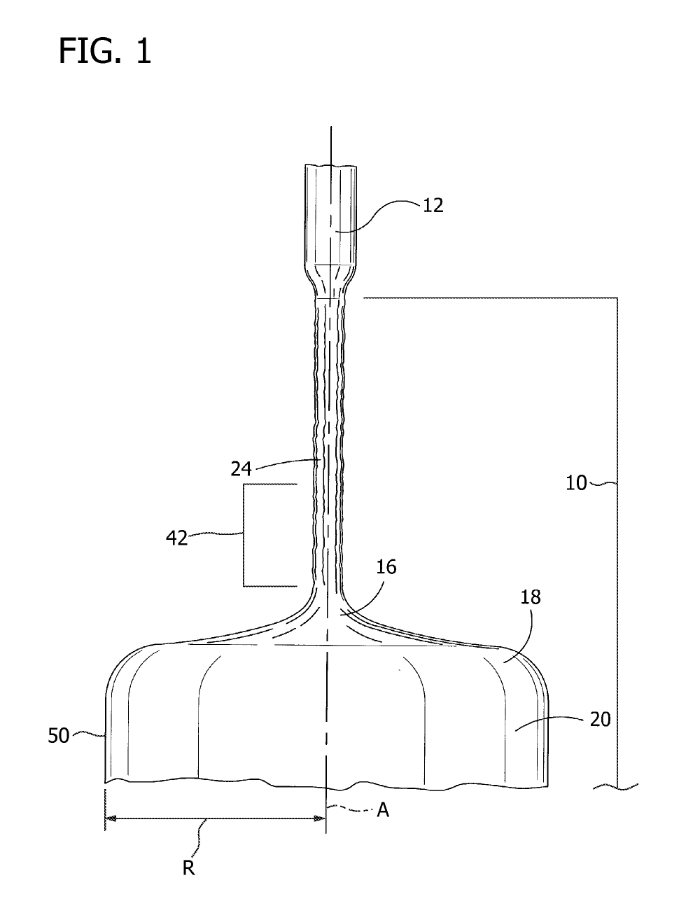

A single crystal silicon ingot 10 produced in accordance with embodiments of the present disclosure and, generally, the Czochralski method is shown in FIG. 1. The ingot includes a neck 24, an outwardly flaring portion 16 (synonymously “cone”), shoulder 18 and a constant diameter main body 20. The neck 24 is attached to a seed 12 that was contacted with the melt and withdrawn to form the ingot 10. The constant diameter portion of the main body 20 has a circumferential edge 50, a central axis A that is parallel to the circumferential edge and a radius R that extends from the central axis to the circumferential edge. The central axis A also passes through the cone 16 and neck 24. The diameter of the main ingot body 20 may vary and, in some embodiments, the diameter may be about 150 mm, about 200 mm, about 300 mm, greater than about 300 mm, about 450 mm or even greater than about 450 mm.

Generally, the melt from which the ingot is drawn is formed by loading polycrystalline silicon into a crucible to form a silicon charge. A variety of sources of polycrystalline silicon may be used including, for example, granular polycrystalline silicon produced by thermal decomposition of silane or a halosilane in a fluidized bed reactor or polycrystalline silicon produced in a Siemens reactor. Once polycrystalline silicon is added to the crucible to form a charge, the charge is heated to a temperature above about the melting temperature of silicon (e.g., about 1412° C.) to melt the charge. Generally, the charge is heated by one or more heaters which are in thermal communication with the crucible. In some embodiments, the charge (i.e., the resulting melt) is heated to a temperature of at least about 1425° C., at least about 1450° C. or even at least about 1500° C. Once the charge is liquefied to form a silicon melt, a silicon seed crystal is lowered to contact the melt. The crystal 12 (FIG. 1) is then withdrawn from the melt with silicon being attached thereto (i.e., with a neck 24 being formed) thereby forming a melt-solid interface near or at the surface of the melt. After formation of the neck, the outwardly flaring cone portion 16 adjacent the neck 24 is grown. The main ingot body 20 having a constant diameter adjacent the cone portion 16 is then grown.

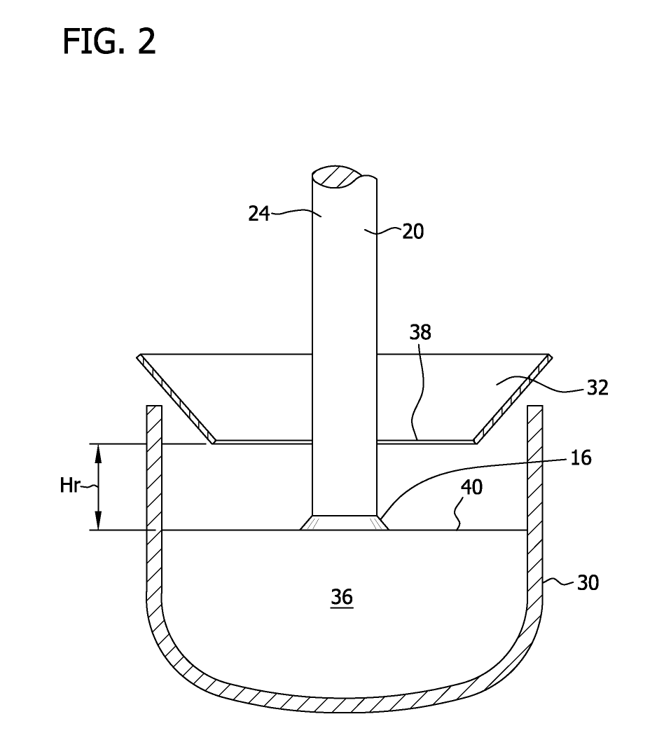

In several embodiments of the present disclosure, heat transfer at the melt-solid interface during growth of the main body 20 is controlled by a device such as a reflector, a radiation shield, a heat shield, an insulating ring, a purge tube or any other similar device capable of manipulating a temperature gradient known generally to one skilled in the art. Heat transfer may also be controlled by adjusting the power supplied to heaters below or adjacent to the crystal melt or by controlling the crucible rotation or magnetic flux in the melt. In a preferred embodiment, heat transfer at the melt-solid interface is controlled using a reflector in proximity to the melt surface as shown in FIG. 2. It should be noted that while the methods of the present disclosure described below are generally described with reference to such a reflector, the methods of the present disclosure are also applicable to the other heat transfer control devices listed above and reference herein to use of a reflector should not be considered in a limiting sense. During formation of the neck 24, heat transfer is typically controlled by use of a device such as the reflector or other device such as a radiation shield, heat shield, insulating ring or purge tube.

Referring now to FIG. 2, a portion of a crystal pulling apparatus is shown. As shown in FIG. 2, an ingot neck 24 has been pulled from the melt surface 40 and the cone-portion 16 of the ingot is beginning to form. The apparatus includes a crucible 30 and a reflector assembly 32 (synonymously “reflector”). As is known in the art, the hot zone apparatus, such as the reflector assembly 32, is often disposed within the crucible 30 for thermal and/or gas flow management purposes. For example, the reflector 32 is, in general, a heat shield adapted to retain heat underneath itself and above the melt 36. In this regard, any reflector design and material of construction (e.g., graphite or gray quartz) known in the art may be used without limitation. As shown in FIG. 2, the reflector assembly 32 has an inner surface 38 that defines a central opening through which the ingot is pulled from the crystal melt 36.

It should be noted that the temperature gradient above the melt surface 40, and thus heat transfer at the melt-solid interface, can be controlled by varying the reflector height above the melt surface. Typically, this reflector height (or “melt gap”), referred to herein as Hᵣ, is measured as the distance between the bottom edge 38 of the reflector 32 and the melt surface 40. The reflector height, Hᵣ, can be varied by either adjusting the position of the reflector apparatus 32 in the hot zone (relative to the surface 40 of the melt, for example) or by adjusting the position of the melt surface 40 in the hot zone (relative to the reflector 32, for example). In a preferred embodiment, the reflector 32 is in a fixed position and the reflector height, Hᵣ, is changed by manipulating the position of the melt surface 40 by moving the crucible 30 within the crystal growing apparatus.

The reflector height Hᵣ can be monitored and adjusted by any method known in the art including, for example, the use of: (i) a vision system and a method for measuring the melt level/position inside the crystal pulling apparatus during ingot growth relative to the reflector positioned above the melt, as described in, for example, U.S. Pat. No. 6,171,391 (which is incorporated herein by reference for all relevant and consistent purposes); (ii) a lift or drive mechanism for raising/lowering the reflector as described in, for example, U.S. Pat. No. 5,853,480 (which is incorporated herein by reference for all relevant and consistent purposes); and/or (iii) a lift or drive mechanism for raising/lowering the crucible which contains the melt, in those instances wherein, for example, the reflector is in a fixed position above the melt surface.

In accordance with the present disclosure, it has been found that dislocations that are propagated upon contacting the seed 12 (FIG. 1) with the melt may be more readily eliminated during neck growth by controlling one or more growth conditions during growth of the silicon neck and, in particular, by controlling one or more of the growth conditions during at least about the last 4 inches (about 10.16 cm) of neck growth. In this regard, it should be understood that, for purposes of the present disclosure, neck growth is considered to terminate once the cone portion 16 (FIG. 1) of the ingot begins to form. Accordingly, about the last 4 inches (about 10.16 cm) of neck in which the growth conditions are controlled (which may be referred to herein as the “terminal portion” of the neck) is about the 4 inches (about 10.16 cm) of neck adjacent (i.e., above) the cone portion 16 of the ingot 10 which is generally designated as “24” in FIG. 1. In this regard, the growth conditions may be controlled beyond about the last 4 inches of neck (about 10.16 cm) without limitation. For example, the growth conditions discussed below may be controlled over about the last 6 inches (about 15.24 cm) or even about the last 8 inches (about 20.32 cm) of neck growth. In some embodiments of the present disclosure, the growth conditions are controlled during formation of the entire length of the neck.

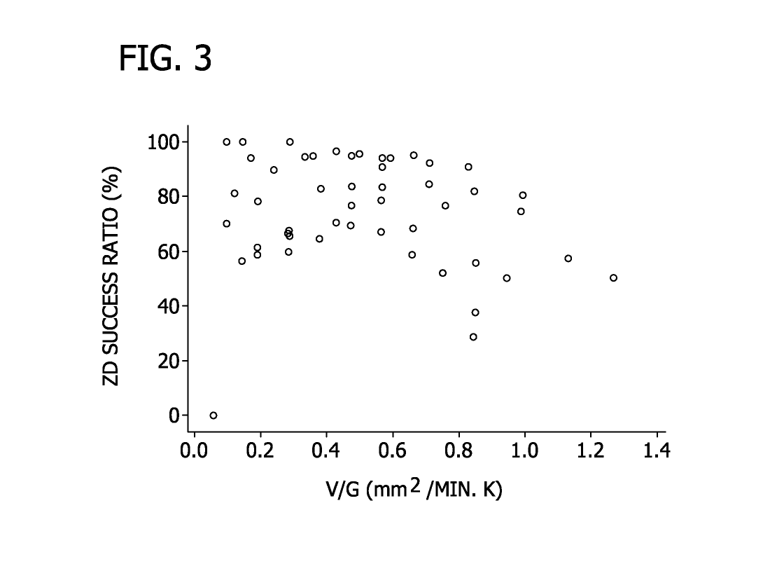

In this regard, it has been found that by controlling the pull rate (V) of the neck and/or controlling the axial temperature gradient over the reflector height (G_{Hr}) such that the ratio V/G_{Hr} is between about 0.80 and about 0.96 mm²/min*K during at least about the last 4 inches (about 10.16 cm) of neck growth, dislocations are more readily eliminated in the neck, thereby increasing the likelihood that the main body of the ingot will not contain dislocations. This result is contrary to conventional wisdom as previous studies indicated that lower ratios of V/G_{Hr} (e.g., about 0.15 to about 0.6 mm²/min*K) over the entire neck length resulted in greater likelihood of not forming dislocations in the main body portion of ingots (see FIG. 3 discussed in Example 1). The ratio of V/G_{Hr} during formation of portions of the neck other than the last 4 inches (about 10.16 cm) may vary and, in some embodiments of the present disclosure, is less than about 1.00 mm²/min*K or even less than about 0.96 mm²/min*K.

It should be noted that G_{Hr} is not the temperature gradient at any specific point within about the last 4 inches (about 10.16 cm) of the neck; rather, G_{Hr}, for purposes of the present disclosure, is an overall or “macro” temperature gradient between the interface and bottom of the device for controlling heat transfer (e.g., reflector). In this regard, for purposes of the present disclosure and unless stated otherwise, G_{Hr} is measured by determining the difference between the temperature of the neck T_{neck} at the bottom of the device for controlling heat transfer (e.g., reflector) and at the neck-melt interface Tₘₑₗₜ and dividing by the distance (Hᵣ) between these two points (i.e., G_{Hr} is equal to (Tₘₑₗₜ−T_{neck})/Hᵣ). In various embodiments of the present disclosure, T_{neck} is modeled using computation modeling software, however T_{neck} may also be determined by measuring the neck temperature directly at the bottom of the device (e.g., measuring T_{neck} at the neck surface at the bottom of the device). Typical temperature ranges for T_{neck} during formation of the last 4 inches (10.16 cm) of neck may be from about 1150° C. to about 1250° C.; however, T_{neck} may be less than about 1150° C. or greater than about 1250° C. without departing from the scope of the present disclosure. Typically T_{neck} during formation of the last 4 inches (10.16 cm) of neck growth is about 1250° C.

Both the growth velocity V and the temperature gradient G_{Hr} may vary (e.g., vary within their commercially practical ranges), however, as described above, in embodiments of the present disclosure V and/or G_{Hr} is controlled such that the ratio V/G_{Hr} is between about 0.80 and about 0.96 mm²/min*K during at least about the last 4 inches (about 10.16 cm) of neck growth. In some embodiments, V is controlled to be at least about 0.2 mm/min during at least about the last 4 inches (10.16 cm) of neck growth or at least about 1 mm/min, at least about 3 mm/min, at least about 5 mm/min, at least about 7.5 mm/min or less than about 10 mm/min, less than about 7.5 mm/min or less than about 5 mm/min (e.g., between about 0.2 mm/min to about 10 mm/min or from about 0.2 mm/min to about 5 mm/min during at least about the last 4 inches (about 10.16 cm) of neck growth). In these and in other embodiments, G_{Hr} is controlled to be at least about 0.2° C./mm during at least about the last 4 inches (10.16 cm) of neck growth or at least about 0.5° C./mm, at least about 1° C./mm, at least about 2° C./mm, at least about 4° C./mm, at least about 6° C./mm, less than about 10° C./mm, less than about 8° C./mm, less than about 6° C./mm, or less than about 5° C./mm (e.g., from about 0.2° C./mm to about 10° C./mm, from about 1° C./mm to about 8° C./mm, or from about 1° C./mm to about 6° C./mm) It should be noted that values of V and/or G_{Hr} other than as recited above may be used during at least about the last 4 inches (about 10.16 cm) of neck growth without departing from the scope of the present disclosure.

In several embodiments of the present disclosure, the velocity pull rate V of the neck during at least about the last 4 inches (about 10.16 cm) of neck growth can be controlled according to a function, f, in which dislocations that are propagated upon contacting the seed 12 (FIG. 1) with the melt are more readily eliminated during neck growth. In some embodiments of the present disclosure, the growth velocity of the neck is controlled by equation (1) during at least about the last 4 inches (about 10.16 cm) of neck growth:

V=−2.826 In (Hᵣ)+14.76 (1).

In this regard, controlling the pull rate according to equation (1) may allow the ratio of pull rate to axial temperature gradient (V/G_{Hr}) to be between about 0.80 and about 0.96 mm²/min*K during at least about the last 4 inches (about 10.16 cm) of neck growth. However in some embodiments of the present disclosure, when the pull rate is controlled according to equation (1), V/G_{Hr} may be less than about 0.80 mm²/min*K or even greater than about 0.96 mm²/min*K without departing from the scope of the present disclosure.

It should be noted that the methods of the present disclosure may generally be used with conventional hot zone arrangements known in the art of Czochralski crystal growth wherein a reflector or other device for controlling heat transfer at the melt-solid interface is positioned above the melt; however the specific pull rate V and overall gradient G_{Hr} may vary as well as the selected value of Hᵣ depending on the type of hot zone used and/or depending on other growth conditions selected by the skilled person for their particular growth process. Generally, however, and according to embodiments of the present disclosure, the ratio of V to G_{Hr} may be controlled to be between about 0.80 and about 0.96 mm²/min*K.

The device height Hᵣ (e.g., reflector height) may vary during about the last 4 inches (about 10.16 cm) of neck. For example, in some embodiments of the present disclosure, Hᵣ may be at least about 20 mm, at least about 40 mm, at least about 60 mm, less than about 120 mm, less than about 100 mm or less than about 80 mm. In this regard, it should be noted that Hᵣ may be bound by any combination of the above-noted parameters such as, for example, from about 20 mm to about 120 mm, from about 40 mm to about 100 mm or from about 40 mm to about 80 mm. Crucible rotation may be controlled to be from about 11 rpm to about 16 rpm (e.g., for about 100-480 kg charges in typical crucibles that may be from about 20 inches to 40 inches in diameter (about 51 cm to about 101 cm)), however other crucible rotation rates (or even no rotation) may be used without limitation.

The methods of embodiments of the present disclosure generally reduce the likelihood that dislocations will propagate from the neck into the ingot body and, in some embodiments, a zero dislocation ingot is produced according to the method. It should be noted that, however, formation of dislocations in the ingot body depends on a variety of factors and is unpredictable. To illustrate, a first ingot grown under a set of known process conditions may be dislocation free, however a second ingot grown under the same conditions may have dislocations. In this regard, the methods of the present disclosure (e.g., controlling V and/or G_{Hr} such that V/G_{Hr} is between about 0.80 and about 0.96 mm²/min*K and/or controlling V by the function V=(−2.826 In (Hᵣ)+14.76)) result in a higher percentage of ingots that are grown without forming dislocations therein relative to conventional methods. In several embodiments of the present disclosure, a plurality of ingots are produced by either (1) controlling V and/or G_{Hr} such that V/G_{Hr} is between about 0.80 and about 0.96 mm²/min*K and/or (2) controlling V according or to the function V=(−2.826 In (Hᵣ)+14.76), wherein at least about 75% of the ingots are dislocation free or at least about 80%, at least about 85%, at least about 90% or even at least about 95% of the ingots are dislocation free. In this regard, the number of ingots that are produced by the recited methods may be at least about 10 ingots, at least about 25 ingots, at least about 50 ingots, at least about 100 ingots or even at least about 500 ingots. It should be noted that in some embodiments of the present disclosure, in addition to the main body of the ingot, dislocations also do not form in the cone portion of the ingot.

Generally, the diameter of the neck Dₙ during neck growth may vary and may depend on a number of factors including the desired diameter of the main ingot body and the pull rate V. In some embodiments of the present disclosure, Dₙ is at least about 4 mm or from about 4 mm to about 15 mm, from about 4 mm to about 10 mm, from about 4 mm to about 8 mm or from about 5 mm to about 8 mm. In some embodiments, Dₙ is controlled during at least about the last 4 inches (about 10.16 cm) of neck growth to be within one or more of the ranges recited above. It should be further noted that the total length of the neck (including the terminal portion in which growth conditions are controlled as described above) in various embodiments of the present disclosure may be at least about 150 mm, at least about 175 mm, at least about 200 mm, at least about 225 mm, less than about 350 mm, less than about 300 mm, less than about 250 mm, less than about 225 mm, less than about 200 mm or less than about 175 mm (e.g., from about 150 mm to about 350 mm, from about 150 mm to about 225 mm or from about 175 mm to about 225 mm).

Although not limited to advanced hot zones, the methods of embodiments of the present disclosure have a preferred use in advanced hot zones used with fast pull rates. An advanced hot zone contains more insulation and/or heat shields within the crystal growth chamber, which generally result in greater radial temperature gradients at the melt-solid interface. Greater radial temperature gradients typically result in more slip dislocations upon contact of the seed crystal with the melt surface and the dislocations formed are more difficult to eliminate due to the increased number.

In some embodiments of the present disclosure, the process for reducing the likelihood of dislocations forming in the ingot body is carried out in a “slow cool” hot zone configuration; that is, the process is performed in any commercial crystal puller having an open or closed hot zone which is capable of achieving the ingot residence times or cooling rates described, for example, in U.S. Pat. Nos. 6,197,111 and 5,853,480, which are incorporated herein by reference for all relevant and consistent purposes. Additionally, the crystal pulling apparatus may be fitted with an upper heater to aid with, for example, control of the cooling rate, such as that shown in U.S. Pat. No. 6,285,011 which is incorporated herein by reference for all relevant and consistent purposes.

It should be understood that the number of neck dislocations and/or ingot dislocations can be quantified and observed by any means known in the art. An exemplary procedure involves etching the neck of a wafer cut from the ingot to expose the dislocations, which are observed and counted under an optical microscope after etching. A typical etch procedure comprises contacting the material with a mixed acid etch (MAE) for about 10 minutes followed by a Wright etch solution for another 10 minutes to expose the dislocations. The number of dislocations, if any, which manifest as etch pits, may then be counted.

### EXAMPLES

The processes of the present disclosure are further illustrated by the following Examples. Accordingly, these Examples should not be viewed in a limiting sense.

### Example 1: Determination of the Relationship Between the V/G_{Hr} Ratio Over the Entire Length of the Neck and Dislocation Growth

The incidence of formation of zero dislocation ingots (“ZD Success Ratio (%)”) was determined over a range of V/G_{Hr} ratios during formation of the neck. The tested V/G_{Hr} ratios were used for formation of the entire length of neck (rather than just the terminal portion). The results of the study are shown in FIG. 3. As can be seen from FIG. 3, selection of V and G_{Hr} over the entire length of the neck such that the ratio of V/G_{Hr} is relatively low (e.g., less than about 6 mm²/min*K) reduced the incidence of dislocation formation in the ingot.

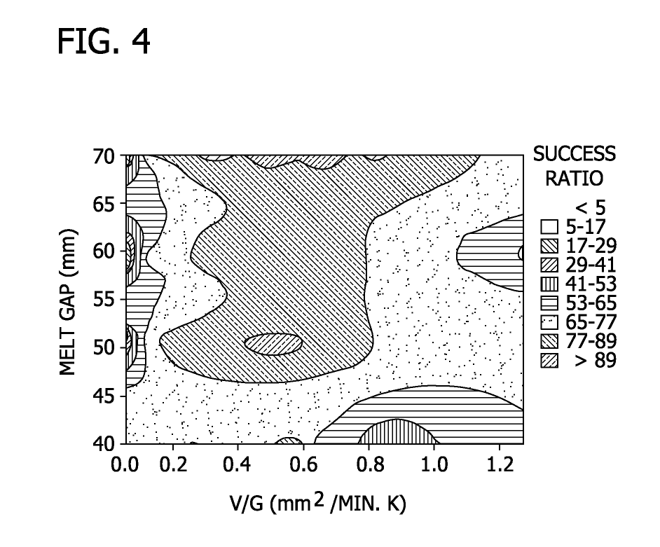

The relationship between V/G_{Hr} and Hᵣ during neck growth is shown in the contour plot of FIG. 4. FIG. 4 illustrates that Hᵣ, in addition to V/G_{Hr}, impacts the formation of dislocation.

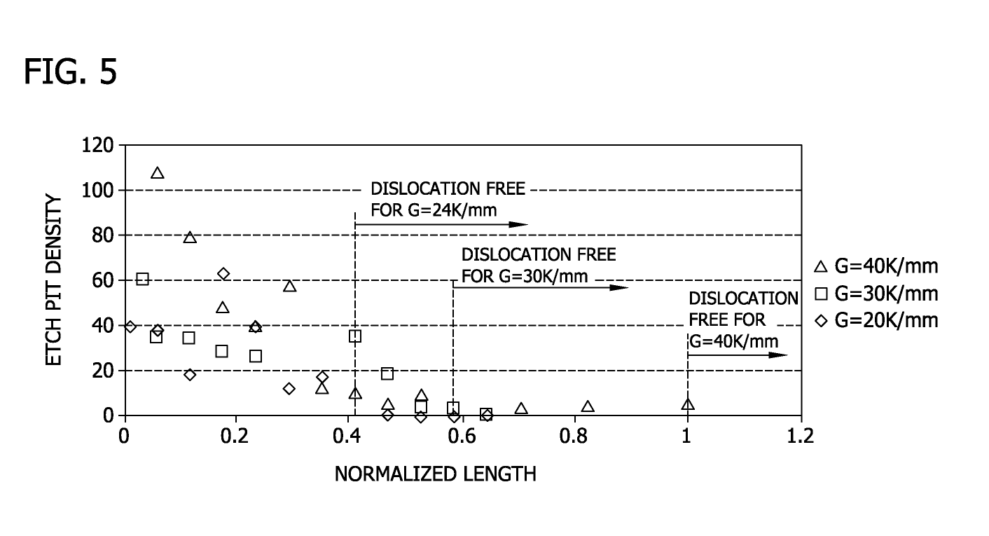

The etch pit density (wherein pits indicate that a dislocation formed in the ingot) was determined for a number of slices cut from different points along an ingot neck, the neck being formed with an axial gradient, G_{Hr}, of 20 K/mm. The same was done for necks formed with G_{Hr} values of 30 K/mm and 40 K/mm. The ingot material was p-type doped. The etch pit density over the normalized length of the neck is shown in FIG. 5.

It should be noted that G_{Hr} as used to determine the various relationships between V, G_{Hr} and Hᵣ in this Example was the difference in temperature between the melt interface Tₘₑₗₜ (e.g., about 1412° C.) and the temperature of the neck at the reflector (e.g., about 1200° C.).

### Example 2: Reduction of Dislocations by Control of V and/or G_{Hr} Such that V/G_{Hr} Ranges from 0.80 to 0.96 mm²/min*K During Formation of the Neck Terminal Portion (Last 4 Inches (10.16 cm))

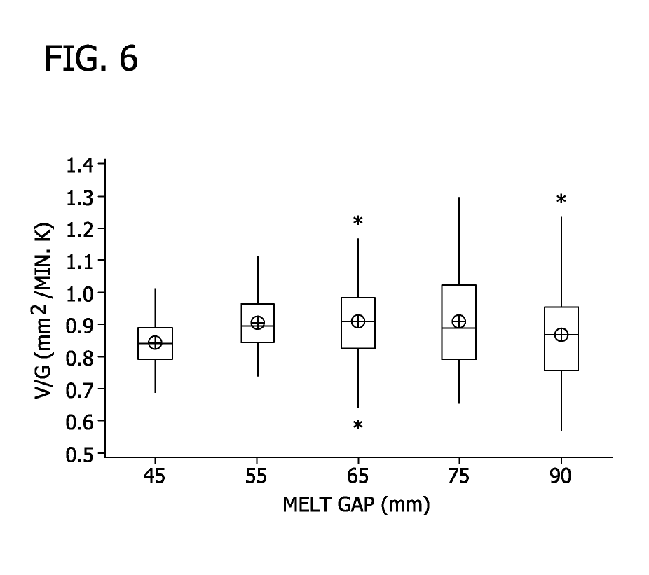

The growth conditions for previously produced ingots that did not contain dislocations (i.e., for “zero dislocation” ingots) in the main ingot body were analyzed. V/G_{Hr} during the last 4 inches (10.16 cm) of neck growth for such zero dislocation ingots was calculated. A box plot showing the range of V/G_{Hr} for zero dislocation ingot growth as well as the average V/G_{Hr} (cross-hairs) and mean V/G_{Hr} (band within the box) for the various reflector heights Hᵣ used during growth is shown in FIG. 6. The boxes of FIG. 6 are bound by the 25^{th} and 75^{th} percentile values. As can be seen from the box plot of FIG. 6, ratios of V/G_{Hr} of between about 0.80 to about 0.96 mm²/min*K over the range of reflector heights that were used in the last 4 inches (10.16 cm) of neck growth represent a large proportion of ingots in which successful zero dislocation growth was achieved. Several outliers (*) are also shown in FIG. 6 for illustration.

When introducing elements of the present disclosure or the preferred embodiments(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above apparatus and methods without departing from the scope of the disclosure, it is intended that all matter contained in the above description and shown in the accompanying figures shall be interpreted as illustrative and not in a limiting sense.

What is claimed is:

1. A method for producing a single crystal silicon ingot, the ingot having a neck, an outwardly flaring cone adjacent the neck and a main body with a constant diameter portion adjacent the cone, the constant diameter portion having a circumferential edge, a central axis that is parallel to the circumferential edge and a radius that extends from the central axis to the circumferential edge, the central axis passing through the cone and neck, the method comprising:
bringing a seed crystal into contact with a silicon melt;
withdrawing the seed crystal from the silicon melt to form a neck adjacent the seed crystal;
growing an outwardly flaring cone adjacent the neck, wherein a growth velocity V and/or a temperature gradient G_{Hr} are controlled during formation of a terminal portion of the neck, such that the ratio V/G_{Hr} is controlled to be from about 0.80 to about 0.96 mm²/min*K, the terminal portion of the neck extending axially from the outwardly flaring cone portion to a distance of at least about 4 inches (about 10.16 cm) from the outwardly flaring cone portion; and
growing a main ingot body having a constant diameter adjacent the cone.

2. The method as set forth in claim 1 wherein there exists a distance Hᵣ between the melt-solid interface and a device positioned above the melt-solid interface selected from the group consisting of a reflector, a radiation shield, a heat shield, an insulating ring and a purge tube, Hᵣ being controlled to be at least about 20 mm during formation of the terminal portion of the neck.

3. The method as set forth in claim 1 wherein there exists a distance Hᵣ between the melt-solid interface and a device positioned above the melt-solid interface selected from the group consisting of a reflector, a radiation shield, a heat shield, an insulating ring and a purge tube, Hᵣ being controlled to be at least about 60 mm during formation of the terminal portion of the neck.

4. The method as set forth in claim 1 wherein the ingot has no dislocations in its main body.

5. The method as set forth in claim 1 wherein the ingot has no dislocations in the cone.

6. The method as set forth in claim 1 wherein there exists a distance Hᵣ between the melt-solid interface and a device positioned above the melt-solid interface selected from the group consisting of a reflector, a radiation shield, a heat shield, an insulating ring and a purge tube, a temperature T_{neck} of the neck at the bottom of the device and a temperature Tₘₑₗₜ of the melt at the neck-melt interface, G_{Hr} being measured by (Tₘₑₗₜ−T_{neck})/Hᵣ.

7. The method as set forth in claim 6 wherein the device positioned above the melt-solid interface is a reflector.

8. The method as set forth in claim 1 wherein the neck has a nominal diameter, Dₙ, and Dₙ is controlled to be at least about 4 mm during at least about the last 4 inches (about 10.16 cm) of neck growth.

9. The method as set forth in claim 1 wherein the neck has a nominal diameter, Dₙ, and Dₙ is controlled to be from about 5 mm to about 8 mm during at least about the last 4 inches (about 10.16 cm) of neck growth.

10. The method as set forth in claim 1 wherein the diameter of the main ingot body is controlled to be about 300 mm.

11. The method as set forth in claim 1 wherein the diameter of the main ingot body is controlled to be greater than about 300 mm.

12. The method as set forth in claim 1, the method further comprising:
loading polycrystalline silicon into a crucible to form a silicon charge; and
heating the silicon charge to a temperature above about the melting temperature of the charge to form the silicon melt.

13. The method as set forth in claim 1 wherein the terminal portion of the neck extends axially from the outwardly flaring cone portion to a distance of at least about 8 inches (about 10.16 cm) from the outwardly flaring cone portion.

14. The method as set forth in claim 1 wherein the total length of the neck as measured from the outwardly flaring cone to the seed crystal is at least about 150 mm.

15. The method as set forth in claim 1 wherein the total length of the neck as measured from the outwardly flaring cone to the seed crystal is at least about 200 mm.

16. A method for producing a single crystal silicon ingot, the ingot having a neck, an outwardly flaring cone adjacent the neck and a main body with a constant diameter portion adjacent the cone, the constant diameter portion having a circumferential edge, a central axis that is parallel to the circumferential edge and a radius that extends from the central axis to the circumferential edge, the central axis passing through the cone and neck, the method comprising:
bringing a seed crystal into contact with a silicon melt;
withdrawing the seed crystal from the silicon melt to form a neck adjacent the seed crystal;
growing an outwardly flaring cone adjacent the neck, wherein a growth velocity V is controlled according to equation (1) during formation of a terminal portion of the neck:
V=−2.826 In (Hᵣ)+14.76 (1),
Hᵣ being the distance between the melt-solid interface and a device positioned above the melt-solid interface selected from the group consisting of a reflector, a radiation shield, a heat shield, an insulating ring and a purge tube, the terminal portion of the neck extending axially from the outwardly flaring cone portion to a distance of at least about 4 inches (about 10.16 cm) from the outwardly flaring cone portion; and
growing a main ingot body having a constant diameter adjacent the cone.

17. The method as set forth in claim 16 wherein the growth velocity V and/or a temperature gradient G_{Hr} are controlled during formation of the terminal portion of the neck, such that the ratio V/G_{Hr} is controlled to be from about 0.80 to about 0.96 mm²/min*K.

18. The method as set forth in claim 17 wherein there exists a temperature T_{neck} of the neck at the bottom of the device and a temperature Tₘₑₗₜ of the melt at the neck-melt interface and G_{Hr} is measured by (Tₘₑₗₜ−T_{neck})/Hᵣ.

19. The method as set forth in claim 16 wherein there exists a distance Hᵣ between the melt-solid interface and a device positioned above the melt-solid interface selected from the group consisting of a reflector, a radiation shield, a heat shield, an insulating ring and a purge tube, Hᵣ being controlled to be at least about 20 mm during formation of the terminal portion of the neck.

20. The method as set forth in claim 16 wherein there exists a distance Hᵣ between the melt-solid interface and a device positioned above the melt-solid interface selected from the group consisting of a reflector, a radiation shield, a heat shield, an insulating ring and a purge tube, Hᵣ being controlled to be from about 20 mm to about 120 mm during formation of the terminal portion of the neck.

21. The method as set forth in claim 16 wherein the ingot has no dislocations in its main body.

22. The method as set forth in claim 16 wherein the ingot has not dislocations in the cone.

23. The method as set forth in claim 16 wherein the device positioned above the melt-solid interface is a reflector.

24. The method as set forth in claim 16 wherein the neck has a nominal diameter, Dₙ, and Dₙ is controlled to be at least about 4 mm during at least about the last 4 inches (about 10.16 cm) of neck growth.

25. The method as set forth in claim 16 wherein the neck has a nominal diameter, Dₙ, and Dₙ is controlled to be from about 4 mm to about 10 mm during at least about the last 4 inches (about 10.16 cm) of neck growth.

26. The method as set forth in claim 16 wherein the diameter of the main ingot body is controlled to be about 300 mm.

27. The method as set forth in claim 16 wherein the diameter of the main ingot body is controlled to be at least about 300 mm.

28. The method as set forth in claim 16, the method further comprising:
loading polycrystalline silicon into a crucible to form a silicon charge; and
heating the silicon charge to a temperature above about the melting temperature of the charge to form the silicon melt.

29. The method as set forth in claim 16 wherein the terminal portion of the neck extends axially from the outwardly flaring cone portion to a distance of at least about 6 inches of neck growth from the outwardly flaring cone portion.

30. The method as set forth in claim 16 wherein the total length of the neck as measured from the outwardly flaring cone to the seed crystal is at least about 150 mm.

31. The method as set forth in claim 16 wherein the total length of the neck as measured from the outwardly flaring cone to the seed crystal is less than about 300 mm.
